(19) United States
(12) Patent Application Publication
(10) Pub. No.: US 2002/0102859 A1
(43) Pub. Date: Aug. 1, 2002

(54) Method for ultra thin film formation

(76) Inventor: Woo Sik Yoo, Palo Alto, CA (US)

Correspondence Address: Theodore P. Lopez, SKJERVEN MORRILL MacPHERSON LLP, Suite 700, 25 Metro Drive, San Jose, CA, 95110-1349, US

(21) Appl. No.: 09/775,835

(22) Filed: Jan. 31, 2001

(51) Int. Cl. H01L 21/31

(52) U.S. Cl. 438/758

(57) ABSTRACT

A method for forming a thin film on a semiconductor wafer. The method includes loading a semiconductor wafer into a process chamber while the process chamber is under vacuum pressure, or alternatively, while the partial pressure of the reactive gas is substantially zero. The process gas is introduced under pressure into the process chamber. The semiconductor wafer is unloaded from the process chamber while the process chamber is under a vacuum pressure, or alternatively while the partial pressure of the reactive gas is substantially zero.

### BACKGROUND OF THE INVENTION

1. Field of the Invention

The present invention generally relates to surface treatment of a semiconductor device and more particularly to a method for forming an ultra thin film on the surface of a semiconductor wafer.

2. Description of the Related Art

It is known that a layer of thin native silicon dioxide (SiO₂) tends to form naturally on bare silicon surfaces. Typically, the presence of the native oxide is undesirable, since the quality and consistency of the native oxide layer is unknown and unpredictable. For this reason, the thin layer of native oxide is generally removed from the surface of the silicon substrate before processing.

In the manufacture of integrated circuits, however, SiO₂ has long been used as a dielectric for integrated circuits because of its excellent thermal stability and relatively good dielectric properties (k˜4.0). Commonly the operational voltage requirement for most integrated circuits is ˜5 volts. Thus, it is frequently desirable to form an SiO₂ insulating layer directly on the surface of the silicon semiconductor substrate or wafer, which will not break or overheat when subjected to the operational voltage.

Unfortunately, most conventional manufacturing processes used for growing thin films are inefficient and wasteful. Typically, most conventional manufacturing processes are batch type processing methods, which may process from between 100 to 150 wafers per processing cycle. Because of the non-uniform nature of the processes and because of an inability to control growth, batch type processes yield many unusable wafers. These conventional processes also require relatively high cycle times. For example, some process can require from 8 to 10 hours for ramping up (heating) and ramping down (cooling) between processing cycles.

### SUMMARY OF THE INVENTION

The present invention provides a method for forming an ultra thin layer of dielectric material on a silicon surface. Preferably, the ultra thin layer can be made of SiO₂ or similar materials, such as SiN and Ta₂O₅. In the present invention, silicon substrates or wafers are loaded onto an appropriate wafer carrier and then introduced into a semiconductor wafer processing system. A wafer transport mechanism can be used to remove a single silicon wafer from the carrier and transport the wafer to a processing chamber. The processing chamber may be, for example, a furnace, an annealer, or other chamber for conducting thermal processing.

In accordance with the present invention, the silicon wafer is loaded into the processing chamber while the processing chamber is under a vacuum pressure. The semiconductor wafer and chamber are heated. Once the chamber reaches a steady-state processing temperature, a process gas, such as oxygen, is introduced into the chamber under pressure. The chemical reaction which takes place in the processing chamber causes the oxygen to react with the surface of the silicon wafer to form an ultra thin SiO₂ layer thereon. The growth rate of the layer is dependent on the pressure of the reactive gas, which can be controlled to produce the desired thickness of the thin film layer. The thickness of the ultra thin SiO₂ layer may be on the order of between about 10 Å to 50 Å. Advantageously, the thin layer of SiO₂ may be formed within about 10-20 minutes in a process temperature of about 800° C. to about 850° C., whereafter the wafer is removed from the chamber and cooled.

In some embodiments, the oxygen may react with Ta (Source TaETO) to form an ultra thin layer of Ta₂O₅. The Ta₂O₅ layer may range in thickness from between about 50 Å to 250 Å. Advantageously, the thin layer of Ta₂O₅ may be formed within about 10-20 minutes in a deposition process temperature of about 300° C. to about 500° C., or in an annealing process of between about 400° C. to about 800° C.

In one aspect of the invention, a method is provided for forming a thin film on a semiconductor wafer. The method includes loading a semiconductor wafer into a process chamber while the process chamber is under vacuum pressure, or alternatively, while the partial pressure of the reactive gas is substantially zero. The process gas is introduced under pressure into the process chamber. The semiconductor wafer is unloaded from the process chamber while the process chamber is under a vacuum pressure, or alternatively while the partial pressure of the reactive gas is substantially zero.

Because the method of the present invention provides a controllable thin layer growth rate, a higher percentage yield of wafers can be achieved in a shorter cycle time. In addition, since higher yields are produced from smaller wafer batch sizes, the overall footprint of the processing system for a required productivity level can be reduced, which saves valuable manufacturing space. Beneficially, the increase in throughput saves energy and reduces waste.

### BRIEF DESCRIPTION OF THE DRAWINGS

FIG. 1 is a simplified diagram of the processing system of the present invention;

FIG. 2 is a flow diagram of the process method in accordance with the present invention;

FIG. 3A is a simplified illustration of an embodiment of a furnace in accordance with the present invention; FIG. 3B is a simplified illustration of a heating element for use in the furnace embodiment of FIG. 3A;

FIG. 4A is a simplified illustration of an embodiment of a furnace in accordance with the present invention; FIG. 4B is a simplified illustration of a heating element for use in the furnace embodiment of FIG. 4A;

FIG. 5A is a simplified diagram of an alternative embodiment of a processing system in accordance with the present invention;

FIG. 5B is a simplified illustration of a furnace for use with the processing system of FIG. 5A;

FIG. 6 is a schematic illustration of a side view of one embodiment of a semiconductor wafer processing system in accordance with the present invention;

FIGS. 7A-7C are simplified illustrations of an embodiment of FIG. 6; and

FIG. 8 is a graph representation of the pressure/temperature variation within the processing chamber as a function of time in accordance with the present invention.

### DETAILED DESCRIPTION

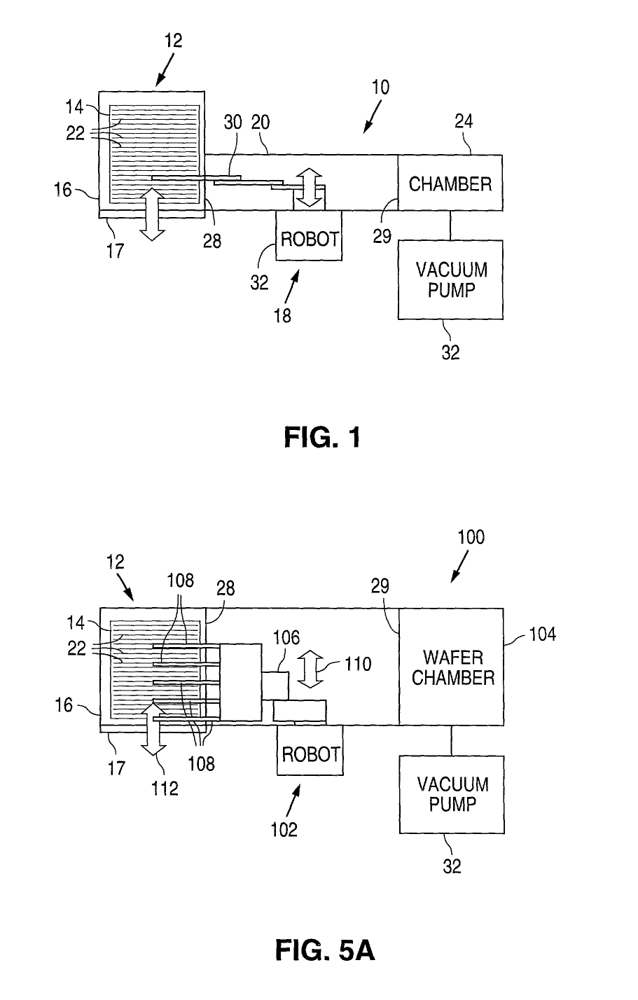

FIG. 1 is a simplified diagram of a processing system 10 that establishes a representative environment for the present invention. Processing system 10 may include a loading station 12, which has multiple platforms 17 for supporting and moving a wafer cassette 14 up and into a loadlock 16. Wafer cassette 14 may be a removable cassette, which is loaded onto platform 17, either manually or with automated guided vehicles (AGV). Wafer cassette 14 may also be a fixed cassette, in which case wafers are loaded onto cassette 14 using conventional atmospheric robots or loaders (not shown). Once wafer cassette 14 is inside loadlock 16, processing system 10 can be pumped down to vacuum. A wafer transport system 18 housed within transfer chamber 20, described in greater detail below, rotates toward loadlock 16 and picks up at least one wafer 22 from cassette 14. A processing chamber 24, also under vacuum, receives wafer 22 from wafer transport system 18 through a gate valve 29.

Wafer transport system 18 is capable of lifting wafer 22 from wafer cassette 14 and, through a combination of linear and rotational translations, transporting the wafer through vacuum chamber valves 28 and 29, and depositing the wafer at the appropriate position within furnace 24. Similarly, wafer transport system 18 is capable of transporting wafer 22 from one processing chamber 24 to another (not shown) and from a processing chamber back to wafer loading station 12.

In one embodiment, wafer transport system 18 includes a robot arm 30 and a controller 32. Robot arm 30 may be any conventional wafer processing robotic arm, which provides R (translation) and Θ (rotation) movements. A gripper or end effector (not shown) may be attached to the end of robot arm 30. The end effector may be made of a heat resistant material, such as quartz, for picking-up and placing wafer 22. An example of a commercially available type of robot arm is the SHR3000 robot (“SHR3000 robot”) from the JEL Corporation of Hiroshima, Japan. The SHR3000 robot can rotate 340°, has 200 mm of vertical motion, and can extend its arms 390 mm in the horizontal plane. Another example of a type of wafer processing robot is disclosed in U.S. patent application Ser. No. 09/451,677, filed Nov. 30, 1999, which is herein incorporated by reference for all purposes.

Once wafer 22 is positioned in chamber 24, transport system 18 retracts and gate valve 29 closes to begin processing. After wafer 22 is processed, gate valve 29 opens to allow transport system 18 to pick-up and remove wafer 22 from the processing chamber.

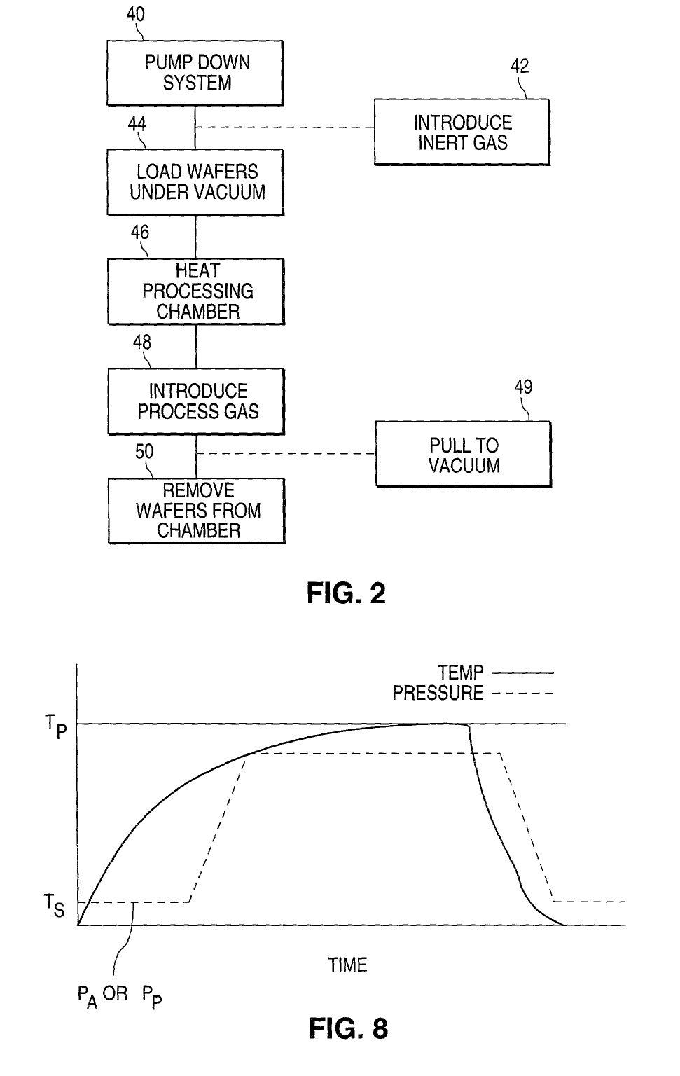

FIG. 2 is a flow diagram of an embodiment of the method of the present invention, which can be performed using processing system 10 of FIG. 1. In this embodiment, processing chamber 24 is a furnace. Furnace 24 may be any conventional type wafer processing furnace, such as any lamp-based or resistively heated furnace. In accordance with the present invention, furnace 24 can be pumped down (40) to a vacuum pressure using a conventional pumping system 32. Pumping down (40) furnace 24 ensures that substantially all moisture and oxygen are removed from the furnace to prohibit the formation of a native SiO₂. Optionally, furnace 24 may be filled with an inert gas (42), such as Argon or Helium, to ensure that residual oxygen and moisture are substantially removed from furnace 24. As further described below, furnace 24 may also be filled with N₂ for diluting the reactive gas.

As understood with reference to the graph of FIG. 8, furnace 24 can be preheated to a steady state temperature T_{S}, which can range from about 200° C. to about 1200° C. At least one silicon wafer 22 is loaded (44) into furnace 24 using transport system 18. After the wafer is loaded (44) into furnace 24, wafer 22 is heated from the initial temperature T_{S} to a processing temperature T_{P}. The processing temperature T_{P} can range from between about 200° C. to about 1200° C.; preferably a range of between about 400° C. to about 1100° C.

In one embodiment, as the wafer temperature in furnace 24 approaches processing temperature T_{S}, a process gas, such as oxygen, is introduced (48) into chamber 24. The rate of flow of the process gas through processing chamber 24 or the partial pressure of the reactive gas is controlled to control the desired rate of growth. It should be understood that when furnace 24 has been pulled to vacuum, the pressure line in FIG. 8 represents the actual pressure P_{A} of furnace 24. Wafer 22 is held in furnace 24 exposed to the oxygen for a time long enough to accomplish the growth of the layer of SiO₂ The thickness of the SiO₂ layer can range from about 10 Å to about 50 Å; preferably between about 10 Å to about 30 Å. Generally, the processing time can range from about 1 to 20 minutes, depending on the process temperature and process ambient conditions.

In an alternative embodiment, the growth rate of the thin film layer can be controlled by controlling the partial pressure P_{P} (FIG. 8) of the reactive gas relative to all gases introduced (48) into furnace 24. For example, an inert gas, such as Helium or Argon, may be introduced into furnace 24, creating a specific chamber pressure. The reactive gas can be introduced such that the partial pressure P_{P} of the reactive gas relative to the chamber pressure is at the desired pressure level for formation of the thin film layer. Optionally, an inert gas, such as N₂ or the like, can be introduced into furnace 24 prior to, with, or after the introduction of the reactive gas to dilute the reactive gas to the desired partial pressure P_{P}. For example, with no intent to limit the invention thereby, under a partial pressure of 1 Torr the growth rate of O₂ can be maintained at 10-20 Å/hr. and at a partial pressure of 1 atm the growth rate of O₂ can be maintained at 1-2 Å/min.

Referring again to FIG. 2, the growth of SiO₂ on the wafer surface can be stopped at processing temperatures by pulling furnace 24 to vacuum (49) before removing wafer 22 from the furnace. The wafer is then removed (50) from chamber 24, using transport system 18. The wafer is allowed to cool to between about 50° C. and 90° C. before being returned to cassette 14. In an alternative embodiment, the growth of the SiO₂ layer can be slowed or almost stopped by removing the wafer from furnace 24. Removal of the wafer causes the wafer to cool below processing temperatures.

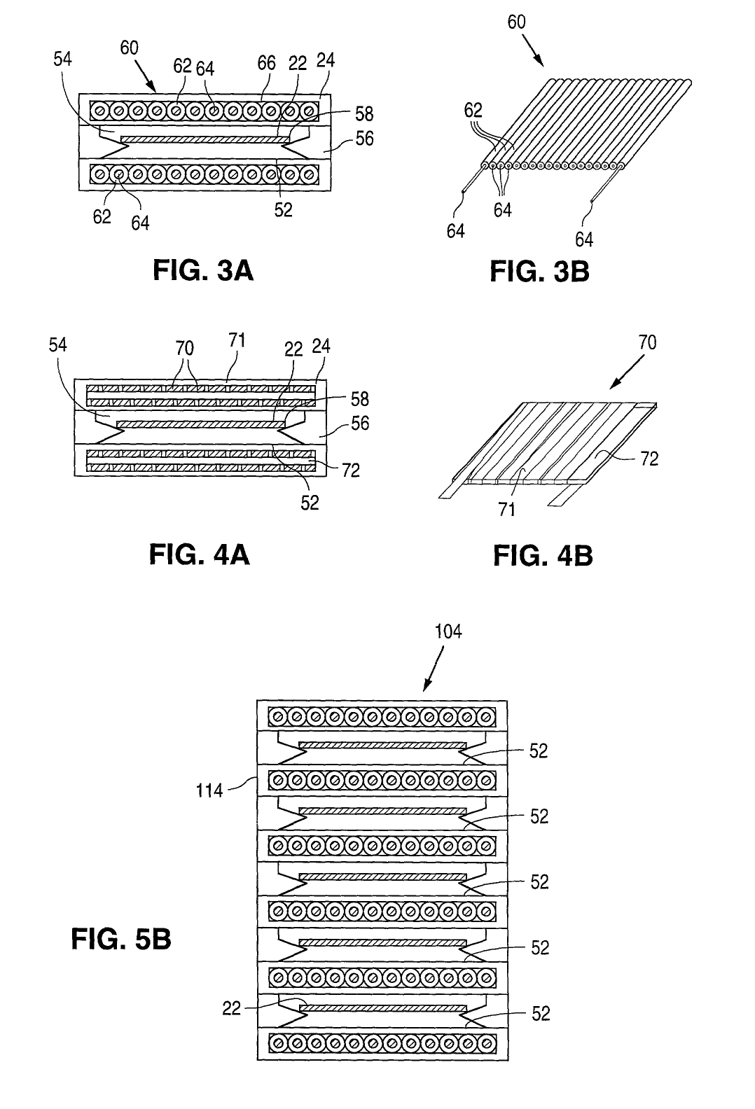

FIGS. 3A and 4A, are simplified illustrations of embodiments of furnace 24. In each embodiment, furnace 24 may include a closed-end process inner chamber 52, which defines an interior cavity 54. In one embodiment, inner chamber 52 may be constructed with a substantially rectangular cross-section, having a minimal internal volume surrounding wafer 22. For example, the volume of inner chamber 52 may be no greater than about 5000 mm³, preferably the volume is less than about 3000 mm³. One result of the small chamber volume is that uniformity in temperature is more easily maintained. Additionally, the small tube volume allows furnace 24 to be made smaller, and as a result, system 10 may be made smaller, requiring less clean room floor space. Inner chamber 52 may be made of quartz, silicon carbide, Al₂O₃, or other suitable material.

In one embodiment, inner chamber 52 includes a wafer support structure 56, which supports wafer 22 during processing. Wafer support structure 56 may be formed into the inner wall of inner chamber 52. An open central portion of wafer support structure 56 allows wafer 22 to be supported on a peripheral edge 58 of wafer 22.

FIGS. 3A, 4A, 3B and 4B illustrate embodiments for use with heating elements of reactor 24. The heating elements are configured to surround inner process chamber 52. In the embodiment, shown in FIGS. 3A and 3B, the heating elements include heating device 60. Heating device 60 includes a plurality of tubes 62, preferably aluminum tubes, disposed in parallel across a top and bottom portion of inner chamber 52. Each aluminum tube 62 includes a resistive heating element 64 disposed therein.

Each resistive heating element 64 includes a resistive heating element core and a filament wire. The core is usually made of a ceramic material, but may be made of any high temperature rated, non-conductive material. The filament wire is wrapped around the core to allow for an optimal amount of radiated heat energy to emanate from the element. The filament wire may be any suitable resistively heatable wire, which is made from a high thermal conductivity material for increased thermal response and high temperature stability, such as SiC, SiC coated graphite, graphite, NiCr, AlNi and other alloys. Preferably, the resistive heating filament wire is made of a combination Al—Ni—Fe material, known commonly as Kantal A-1 or AF, available from Omega Corp. of Stamford, Conn.

Each tube 62 is in relative close proximity to each other element, for example, each tube 62 may be spaced between about 0 mm and 50 mm, preferably between about 1 mm and 20 mm. Accordingly, the close spacing provides for an even heating temperature distribution across wafer 22 when positioned in inner chamber 52. The plurality of tubes 62 are contained in a quartz container 66 to reduce the possibility of metal contamination.

FIGS. 4A and 4B illustrate an alternative embodiment of the heating element of reactor 24. In this embodiment, heating device 70 includes a ribbon shaped heating element 71 wrapped around a quartz plate 72. Each heating device 70 can be disposed in parallel across a top and bottom portion of inner chamber 52. Alternatively, heating element 71 can include a plurality of individual resistive heating elements combined to form the heating element.

Advantageously, a direct line voltage of between about 100 volts and about 500 volts may be used to power the resistive elements described above. Thus, no complex power transformer is needed in the present invention for controlling the output of the resistive heating elements.

FIG. 5A is a simplified diagram of an alternative embodiment of processing system 100 in accordance with the present invention. Processing system 100 includes components consistent with the description of the embodiments above, where like components are numbered similarly. The alternative embodiment of FIG. 5A includes a transport system 102 capable of simultaneously transporting a plurality of wafers 22 from loadlock 16 to process chamber 104. Further, process chamber 104 is capable of simultaneously receiving and processing the plurality of wafers 22. In this alternative embodiment, wafer transport system 102 includes a robot arm 106 coupled to a plurality of end-effectors 108. End-effectors 108 are arranged in a stacked configuration and spaced apart with sufficient space to simultaneously access a plurality of wafers 22 in cassette 14. Wafer transport system 102 is capable of lifting the multiple wafers 22 from wafer cassette 14 and, through a combination of linear and rotational translations, transporting wafers 22 through vacuum chamber valves 28 and 29, and depositing the wafer at the appropriate position within processing chamber 104. Similarly, wafer transport system 102 is capable of transporting wafers 22 from one processing chamber 104 to another (not shown) and from a processing chamber back to wafer loading station 12.

In one embodiment, robot arm 106 is moved up and down as indicated by arrow 110. In this manner, robot arm 106 can move the plurality of end-effectors 108 into position to pick up the wafers. In this embodiment, robot arm 106 controls five end-effectors 108. Thus, each end effector 108 is capable of servicing approximately 20% of wafer cassette 14.

In yet another embodiment, robot arm 106 is fixed for movement in the vertical direction. In this embodiment, wafer loading station 12 includes the capability of moving wafer cassette 14 in the direction indicated by arrow 112 once wafer cassette 14 is in loadlock 16. Wafer cassette 14 is moved incrementally a distance sufficient to allow each end-effector 108 to access a portion of wafers 22.

FIG. 5B is a simplified illustration of a front view of furnace 104. As shown in FIG. 5B, furnace 104 is a series of stacked furnaces including a plurality of inner chambers 52. Each inner chamber 52 is capable of receiving one wafer 22 delivered by robot arm 106 and end effectors 108 (FIG. 5A). Advantageously, in the stacked arrangement, the bottom heating device 114, for example, can serve as the beating device for a subsequent inner chamber 52. This arrangement saves energy, materials, and floor space.

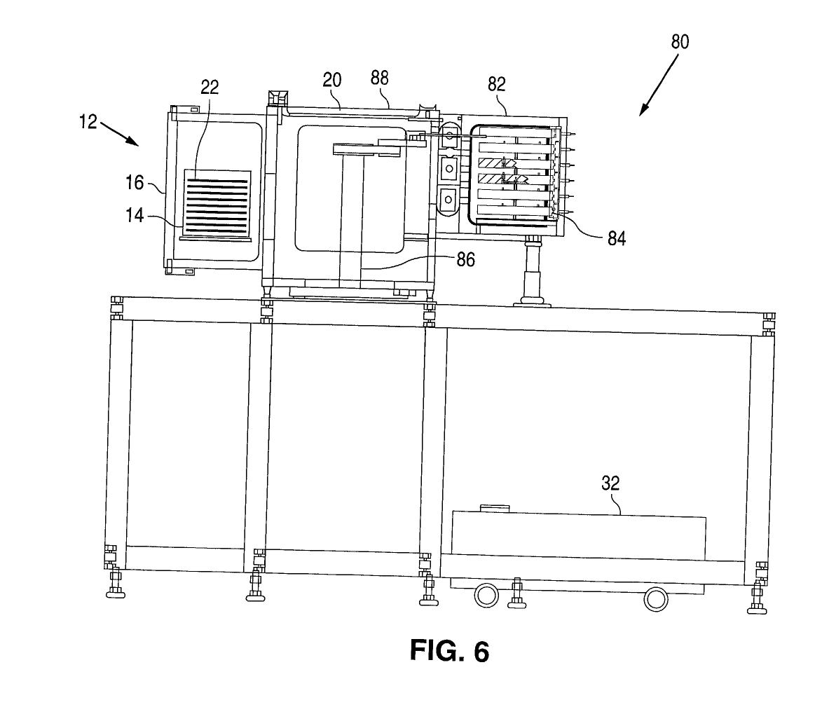

FIG. 6 is an illustration of yet another alternative embodiment of processing system 80 in accordance with the present invention. Processing system 80 includes components consistent with the description of the embodiments above, where like components are numbered similarly. Processing system 80 includes a process chamber 82 capable of processing a plurality of wafers 22. In this embodiment, wafer 22 is removed from cassette 14 and transported through process system 80 by wafer transport system 86 into process chamber 82. Wafer transport system 86 lifts a wafer 22 from wafer cassette 14 and, through a combination of linear and rotational translations, transports the wafer through transport chamber 88, and deposits the wafer at the appropriate position within furnace 82. Similarly, wafer transport system 86 is capable of transporting wafer 22 from one processing chamber to another (not shown) and from a processing chamber back to wafer loading station 12.

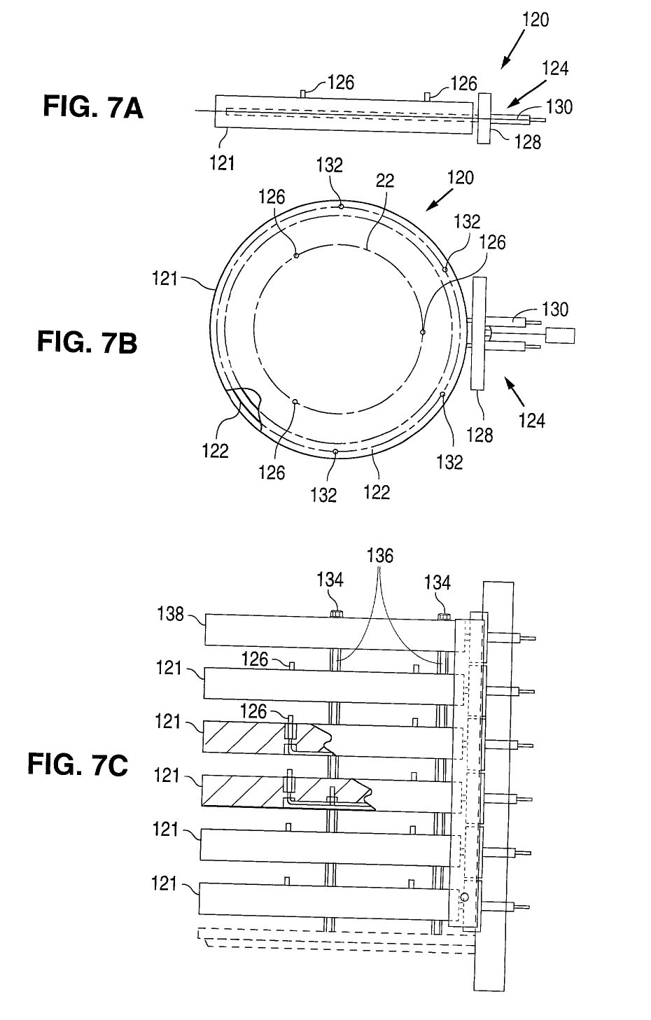

FIGS. 7A and 7B show an embodiment of process chamber 82 (FIG. 6) which includes a heating assembly 120 includes heating member or plate 121, at least one heat source 122, and a coupling mechanism 124. Heating assembly 120 may be positioned suspended within process chamber 82, in a cantilevered relationship on a wall of process chamber 82. Alternatively, heating assembly 120 may rest on mounts emanating up from a floor of process chamber 82.

Heating plate 121 may have a large mass relative to wafer 22, and may be fabricated from a material, such as silicon carbide, quartz, inconel, aluminum, steel, or any other material that will not react at high processing temperatures with any ambient gases or with wafer 22. Arranged on a top surface of heating plate 121 may be wafer supports 126. In a preferred embodiment, wafer supports 126 extend outward from the surface of heating plate 121 to support the single wafer 22. Wafer supports 126 are sized to ensure that wafer 22 is held in close proximity to heating plate 121. For example, wafer supports 126 may each have a height of between about 50 μm and about 20 mm, preferably about 2 mm to about 8 mm. The present invention includes at least three wafer supports 126 to ensure stability. However, the total contact area between wafer supports 126 and wafer is less than about 350 mm², preferably less than about 300 mm².

Heating plate 121 may be formed into any geometric shape, preferably a shape which resembles that of the wafer. In a preferred embodiment, heating plate 121 is a circular plate. The dimensions of heating plate 121 may be larger than the dimensions of wafer 22, such that the surface area of the wafer is completely overlaid by the surface area of heating plate 121. Preferably, the diameter of heating plate 121 may be no less than the diameter of wafer 22, preferably, the diameter of heating plate 121 is greater than the diameter of wafer 22. For example, the radius of heating plate 121 is greater than the radius of wafer 22 by about a length of between about 1 mm and 100 mm, preferably 25 mm.

In one embodiment, on a periphery of heating plate 121 is coupled at least one heat source 122. Heat source 122 may be a resistive heating element or other conductive/radiant heat source, which can be made to contact a peripheral portion of heating plate 121 or may be embedded within heating plate 121. The resistive heating element may be made of any high temperature rated material, such as a suitable resistively heatable wire, which is made from a high mass material for increased thermal response and high temperature stability, such as SiC, SiC coated graphite, graphite, AlCr, AlNi and other alloys. Resistive heating elements of this type are available from Omega Corp. of Stamford, Conn.

Coupling mechanism 124 includes a mounting bracket 128 and electrical leads 130 to provide an electrical power connection to heat source 122. Mounting bracket 128 may be coupled to an internal wall of process chamber 82 using conventional mounting techniques. Once mounted, electrical leads 130 can extend outside of process chamber 82 to be connectable to an appropriate power source. The power source may be a direct line voltage of between about 100 volts and about 500 volts.

FIG. 7C is an illustration of yet another embodiment of the present invention. As shown in the figure, a plurality of heating plates 121 may be stacked together within process chamber 82. In a preferred embodiment, mounting holes 132 (FIG. 7B) are provided on a periphery of heating plates 121 and extend therethrough. Any appropriate number of mounting holes may be used to ensure that each heating plate 121 is supported. However, each mounting hole is positioned, such that the loading/unloading of wafer 22 is not hampered. Preferably, as illustrated in FIG. 7B, each mounting hole 132 is positioned on a half of heating plate 121 near coupling mechanism 124. This arrangement ensures that the loading/unloading of wafer 22 onto heating member 120 is not impeded. In one embodiment, a rod 134 or similar member is threaded through mounting holes 132 and spacers 136. Spacers 136 keep heating plate 121 an appropriate distance away from one another, which ensures that wafer supports 126 and wafer 22 can be fit in-between the stacked heating plate by, for example, robot arm 106 (FIG. 5A) or wafer transport system 86 (FIG. 6). The distance between the stacked heating plates may be between about 10 mm and 50 mm, for example, about 20 mm. The top most stacked heating plate 138 may be the same in structure and performance as the other heating plates 121, except that the top most heating plate 138 may not be used to support wafer 22.

The description of the invention given above is provided for purposes of illustration and is not intended to be limiting. The invention is set forth in the following claims.

What is claimed is:

1. A method for forming a thin film on a semiconductor wafer comprising:
heating a process chamber to a steady-state processing temperature;
loading a semiconductor wafer into said process chamber;
introducing a reactive gas into said process chamber at a preselected pressure; and
unloading the semiconductor wafer from said process chamber at said processing temperature.

2. The method of claim 1, wherein said processing temperature is between 800° C. and 1200° C.

3. The method of claim 1, wherein said processing temperature is between 200° C. and 800° C.

4. The method of claim 1, wherein said introducing of said reactive gas includes introducing an inert gas, wherein said molecular ratio between said reactive gas and said inert gas causes said reactive gas to be at said preselected pressure.

5. The method of claim 4, wherein said preselected pressure of said reactive gas is between 0.1 Torr and 760 Torr.

6. The method of claim 4, wherein said inert gases is taken form the group consisting of argon, helium and nitrogen.

7. The method of claim 1, wherein said preselected pressure of said reactive gas is between 0.1 Torr and 760 Torr.

8. The method of claim 1, wherein said preselected pressure comprises a partial pressure of said process chamber between about 0.1 Torr and 760 Torr.

9. The method of claim 1, wherein said reactive gas comprises a gas taken from the group consisting of O₂, NH₃, TaETO, NO, N₂O, and H₂O.

10. The method of claim 1, further comprising diluting said reactive gas with N₂ to reduce said preselected pressure.

11. A method for forming a thin film on a semiconductor wafer comprising:
heating a process chamber to a steady-state processing temperature;
loading a semiconductor wafer into a process chamber, said process chamber being under vacuum pressure;
introducing a process gas under a pressure into said process chamber; and
removing said semiconductor wafer from said process chamber while said process chamber is under vacuum pressure.

12. The method of claim 11, wherein said loading of a semiconductor wafer comprises loading a plurality of semiconductor wafers and removing of said semiconductor wafer comprises removing said plurality of semiconductor wafers.

13. The method of claim 12, wherein said loading and removing of a plurality of wafers are accomplished using a robot arm comprising multiple end-effectors for grasping said plurality of wafers.

14. A method for forming a thin film on a semiconductor wafer comprising:
heating a process chamber to a steady state temperature;
pulling a vacuum pressure in said chamber;
loading at least one semiconductor wafer into a process chamber while said process chamber is under said vacuum pressure;
introducing a process gas under pressure into said process chamber; and
removing the at least one semiconductor wafer from said process chamber.

15. The method of claim 14, wherein said steady state temperature is a process temperature between about 800° C. and 1200° C.

16. The method of claim 14, wherein said vacuum pressure is maintained in the range of between 0.1 Torr and 760 Torr.

17. The method of claim 14, wherein said process chamber is a resistively heated furnace.

18. The method of claim 14, wherein said process gas is O₂.

19. The method of claim 14, further comprising pulling a vacuum pressure after said introducing of said process gas under pressure.

20. The method of claim 14, wherein said removing is accomplished while said process chamber is under said vacuum pressure.

21. The method of claim 14, wherein said loading of said at least one semiconductor wafer is accomplished in the absence of substantially all oxygen.
